(19) United States
(12) Patent Application Publication
(10) Pub. No.: US 2021/0183671 A1
(43) Pub. Date: Jun. 17, 2021

(54) OPTICAL HEATING DEVICE

(71) Applicant: Ushio Denki Kabushiki Kaisha, Tokyo (JP)

(72) Inventors: Takafumi MIZOJIRI, Tokyo (JP); Satoru FURUE, Tokyo (JP); Takeshi NAKATANI, Tokyo (JP)

(73) Assignee: Ushio Denki Kabushiki Kaisha, Tokyo (JP)

(21) Appl. No.: 17/119,046

(22) Filed: Dec. 11, 2020

(30) Foreign Application Priority Data
Dec. 13, 2019 (JP) 2019-225325

(51) Int. Cl. H01L 21/67; G01J 5/08

(52) U.S. Cl. CPC H01L 21/67115; H01L 21/67248; G01J 5/0896

(57) ABSTRACT

An optical heating device is an optical heating device for heating a heating target, includes: an LED element disposed to face the heating target and emitting light for heating the heating target; and a radiation thermometer having a light receiver and measuring a temperature of a heat source that is a source of infrared light that enters the light receiver in accordance with an intensity of the infrared light in a predetermined range of wavelengths to be measured, the light receiver having a light receiving area where the light receiver is capable of receiving light, and being disposed such that the light receiving area contains the heating target, the LED element emitting light of a wavelength outside the range of wavelengths to be measured by the radiation thermometer and being disposed outside the light receiving area.

### BACKGROUND OF THE INVENTION

### Field of the Invention

The present invention relates to an optical heating device, and more particularly to an optical heating device that provides heating by light irradiation using LED elements, and measures temperature with a radiation thermometer.

### Description of the Related Art

Optical heating devices that use halogen lamps or LED elements have been known before as one of the equipment that performs thermal treatment of a heating target in a production process. Optical heating devices equipped with a temperature measurement feature using a thermocouple or radiation thermometer for temperature management are used, in particular, for semiconductor production processes, in which the heating temperature has direct bearing on the quality of end products.

For example, Patent Document 1 specified below describes an optical heating device that uses LED elements and measures temperature with a radiation thermometer. The optical heating device described in the Patent Document 1 specified below is configured such that the wavelength of the light emitted by LED elements to be used for the heating (hereinafter referred to as “heating light”) is different from the range of wavelengths of infrared light to be measured by the radiation thermometer (hereinafter referred to as “range of wavelengths to be measured”) so that the heating light does not influence temperature measurement by the radiation thermometer. The optical heating device is described as having the radiation thermometer disposed such as to measure the temperature from the opposite side from the LED elements relative to the heating target.

According to the configuration of the Patent Document 2 specified below, similarly to the optical heating device of the Patent Document 1 specified below, the wavelength of the heating light emitted by LED elements is differed from the range of wavelengths to be measured by the radiation thermometer so that the heating light does not influence temperature measurement by the radiation thermometer. The optical heating device described in the Patent Document 2 specified below, however, is described as having the radiation thermometer disposed such as to measure the temperature from one side of the heating target.

### PRIOR ART DOCUMENT

### Patent Document

Patent Document 1: Japanese Patent No. 4940635

Patent Document 2: Japanese Patent No. 5084420

### SUMMARY OF THE INVENTION

Through intensive research, the inventors of the present invention have found out that accurate temperature measurement is not possible with an optical heating device with LED elements designed to emit heating light of a wavelength that is differed from the range of wavelengths to be measured by the radiation thermometer. This issue is further explained below.

The radiation thermometer measures the intensity of infrared light within the range of wavelengths to be measured that is measurable by the light receiver, and determines the temperature of the heating target on the basis of the relationship between a predetermined temperature of the heating target and the intensity of infrared light corresponding to that temperature. Namely, it is desirable that the infrared light in the range of wavelengths to be measured the light receiver of the radiation thermometer receives be solely the infrared light radiated from the heating target.

In heating the heating target, however, other components of the optical heating device are also inevitably heated due to thermal diffusion, power supply and so on. That is to say, during the heating of the heating target, it is possible that other components are also radiating infrared light as heat sources.

When infrared light of a predetermined wavelength band radiated from other components than the heating target is received by the light receiver of the radiation thermometer with the infrared light radiated from the heating target, the intensity of that infrared light is superimposed on the intensity of the infrared light radiated from the heating target, as a result of which a result different from the actual temperature of the heating target is produced.

The light source that emits the heating light is considered to be heated to a high temperature during the heating of the heating target. Namely, in the optical heating device that uses LED elements, the LED elements themselves become hot when heating the heating target. The LED elements generate heat and become hot because current is applied so as to cause the LED elements to emit light for heating the heating target. This heats up the LED elements, substrates and others that form the optical heating device, whereby heat rays of 1 μm or more, for example, are radiated and cause the noises for the radiation thermometer. Since the intensity of light a single LED element alone generates is low, several hundreds to several thousands LED elements are used as the light source when heating a silicon wafer or the like.

The temperature of the LED elements rises by 10° C. or more, in some cases 100° C. or more when current is applied. Namely, the LED elements not only emit the heating light but also radiate infrared light outside the range of wavelengths to be measured by the radiation thermometer as a heat source.

That is, when the LED elements generate heat and the infrared light radiated from the LED elements is received by the light receiver of the radiation thermometer, the radiation thermometer produces a measurement result that is different from the actual temperature of the heating target. Therefore, accurate temperature measurement is not possible by merely using different wavelengths for the heating light emitted by the LED elements and the range of wavelengths to be measured by the radiation thermometer.

In view of the problem described above, it is an object of the present invention to provide an optical heating device capable of accurate temperature measurement.

An optical heating device of the present invention is an optical heating device for heating a heating target, including: an LED element disposed to face the heating target and emitting light for heating the heating target; and a radiation thermometer having a light receiver and measuring a temperature of a heat source that is a source of infrared light that enters the light receiver in accordance with an intensity of the infrared light in a predetermined range of wavelengths to be measured, the light receiver having a light receiving area where the light receiver is capable of receiving light, and being disposed such that the light receiving area contains the heating target, the LED element emitting light of a wavelength outside the range of wavelengths to be measured by the radiation thermometer and being disposed outside the light receiving area.

The LED element for heating a heating target is disposed such that a heating light emitting surface thereof is to face the heating target so as to emit heating light toward the heating target. When a current necessary for light emission flows, the LED element projects heating light toward the heating target to heat up the object.

The range of wavelengths of infrared light to be measured by the radiation thermometer is adjusted in accordance with the range of temperatures to be measured. The range of wavelengths of infrared light to be measured is adjusted in accordance with the characteristics of the devices forming the light receiver and with a filter that lets infrared light of a specific range of wavelengths pass through.

The path of infrared light proceeding toward the light receiver of the radiation thermometer can be adjusted by an optical system such as a lens and a mirror. A light receiving area is a distance in which the infrared light radiated from a heat source can reach the light receiver while keeping a measurable intensity, a range of area where the light receiver can measure the intensity of the infrared light.

The range of area where the light receiver can measure the intensity of the infrared light includes an area where infrared light directly enters the light receiver and an area where infrared light can be guided to the light receiver by an optical system such as a lens and a mirror. In addition, the range includes an area where the infrared light is guided to the light receiver of the radiation thermometer by being reflected by the heating target, in cases where the heating target reflects, by its nature, the infrared light outside the range of wavelengths that can be measured by the light receiver of the radiation thermometer. This will be further explicated later with reference to FIG. 2.

When wavelengths included in the heating light emitted by the LED element are contained in the range of wavelengths to be measured by the radiation thermometer, the light receiver of the radiation thermometer measures the heating light emitted by the LED elements together with the infrared light radiated from the heating target, as a result of which the temperature determined by the radiation thermometer will be different from the actual temperature of the heating target. Therefore, the LED elements are configured to emit heating light of wavelengths outside the range of wavelengths to be measured by the radiation thermometer.

The LED element that emits heating light of wavelengths outside the range of wavelengths to be measured by the radiation thermometer herein refers to an LED element that emits light having a main wavelength outside the range of wavelengths to be measured by the radiation thermometer and that emits light containing at least 5% or more of the intensity peak of its intensity distribution being outside the range of wavelengths to be measured by the radiation thermometer.

When heating the heating target, current is applied to the LED element to emit heating light because of which heat is generated. Thus, infrared light is radiated, due to the heat the LED element itself generates during the light emission, as well as the heat accumulated therearound, such as the substrate, as heat sources. When the LED element is disposed within the light receiving area, the light receiver of the radiation thermometer measures the infrared light radiated from the LED element as the heat source with the infrared light radiated from the heating target, as a result of which the temperature determined by the radiation thermometer differs from the actual temperature of the heating target. Accordingly, the LED element is disposed outside the light receiving area.

In the optical heating device described above, the radiation thermometer may be disposed on an opposite side from a side where the LED element is disposed relative to the heating target.

In the optical heating device described above, the radiation thermometer may be disposed on a same side as a side where the LED element is disposed relative to the heating target.

The radiation thermometer, whether it is disposed on the same side of the heating target as the side where the LED element is disposed, or on the opposite side of the heating target from the side where the LED element is disposed, need only be disposed such that the LED element is outside the light receiving area so that the infrared light from the LED element as the heat source does not enter the light receiver of the radiation thermometer. Whichever side it is disposed, the radiation thermometer may be disposed on a lateral side of the heating target.

When the optical heating device described above has the radiation thermometer disposed on the same side as the side where the LED element is disposed relative to the heating target, the optical heating device may include a plurality of LED units, each LED unit including a plurality of the LED elements disposed on a same substrate, the plurality of LED units being disposed with a space therebetween in a direction parallel to a surface of the substrate, the radiation thermometer being disposed such that the light receiving area of the light receiver is contained in a specific one of the spaces.

A plurality of LED elements are disposed on the same substrate of each LED unit. Configuring LED units enables common use of a power source, cooling mechanism and the like by the LED elements disposed on the same substrate, which allows a size reduction of the entire device.

The LED units are disposed with a space therebetween in a direction parallel to a surface of the substrate, and the radiation thermometer may be disposed in a region opposite from the light emitting surface of the heating light of the LED elements.

When the optical heating device described above has the radiation thermometer disposed on the same side as the side where the LED element is disposed relative to the heating target, the optical heating device may include a holder for holding the plurality of LED units in a coplanar manner, the holder including an aperture part communicated to the specific one of the spaces in a direction perpendicular to the surface of the substrate, the light receiver of the radiation thermometer being disposed farther from the LED elements than the holder and such that the light receiving area of the light receiver is contained in the aperture part and the specific one of the spaces.

With a plurality of LED units held in a coplanar manner by the holder, the heated surface of the heating target can be irradiated uniformly with the heating light. The LED units are disposed with a space therebetween in a direction parallel to a surface of the substrate, and the holder has an aperture part communicated to a specific one of the spaces in a direction perpendicular to the surface of the substrate. Thus, the radiation thermometer can be disposed in a region opposite from the light emitting surface of the heating light of the LED elements and farther from the LED elements than the holder.

When the radiation thermometer is disposed in a region opposite from the light emitting surface of the heating light of the LED elements, the radiation thermometer is disposed such as to have the light receiving area contained in the specific one of the spaces and the aperture part. This configuration enables measurement of infrared light emitted by the heating target from the region opposite from the light emitting surface of the heating light of the LED elements, without including the LED elements in the light receiving area.

The radiation thermometer need to be oriented or disposed at a position such that its light receiver does not receive infrared light radiated from the LED element as the heat source even when the infrared light is reflected by the heating target.

In the optical heating device wherein the radiation thermometer is disposed on the same side as the side where the LED element is disposed relative to the heating target, the radiation thermometer may include an optical waveguide for guiding infrared light radiated from the heating target toward the light receiver.

The optical waveguide guides the infrared light radiated from the heating target toward the light receiver of the radiation thermometer. The optical waveguide guides only the infrared light radiated from the heating target to the light receiver to minimize the influence of infrared light radiated from other components than the heating target, so that the influence of the infrared light radiated from the LED element can be reduced, and the accuracy of temperature measurement will be improved.

In the optical heating device described above, the range of wavelengths to be measured may be from 1.9 μm to 4.0 μm.

As will be explicated later in detail, the emissivity of an Si substrate is dependent on wavelength in some temperature range as shown in FIG. 3. For example, when the wavelength is smaller than 1.9 μm, the emissivity varies largely depending on the wavelength. On the other hand, when the wavelength is larger than 4.0 μm, the emissivity is more susceptible to the influence of radiation from other components (ambient light). Variation in emissivity relative to wavelength is minimized in the wavelengths from 1.9 μm to 4.0 μm, and the accuracy of temperature measurement for this range of infrared light will be higher.

Accordingly, the range of wavelengths of infrared light to be measured is set to 1.9 μm to 4.0 μm, so that the radiation thermometer is less susceptible to the infrared light radiated from other heat sources, and the accuracy of temperature measurement of the heating target (especially when it is the silicon wafer) will be improved.

Further, in the optical heating device described above, the range of wavelengths to be measured may be from 1.9 μm to 2.6 μm.

According to the present invention, an optical heating device capable of accurate temperature measurement can be provided.

### BRIEF DESCRIPTION OF THE DRAWINGS

FIG. 1A is a schematic view illustrating a configuration of a first embodiment of the optical heating device.

FIG. 1B is a schematic view of the optical heating device of FIG. 1A when viewed from a heating target.

FIG. 2 is a schematic view illustrating a configuration of a radiation thermometer and a light receiving area.

FIG. 3 is a graph illustrating a relationship between wavelengths of infrared light and emissivity at various temperatures of a silicon wafer.

FIG. 4 is a schematic view illustrating a configuration of a second embodiment of the optical heating device.

FIG. 5 is a schematic view illustrating a configuration of a third embodiment of the optical heating device.

FIG. 6 is a schematic view illustrating a configuration of a fourth embodiment of the optical heating device.

FIG. 7 is a schematic view illustrating a configuration of another embodiment of the optical heating device.

FIG. 8 is a schematic view illustrating a configuration of yet another embodiment of the optical heating device.

### DETAILED DESCRIPTION OF THE PREFERRED EMBODIMENTS

An optical heating device according to the present invention is described with reference to the drawings. Note that the drawings referred to below are all schematic illustrations and dimensional ratios and numbers of parts on the drawings do not necessarily match the actual dimensional ratios and numbers of parts.

### First Embodiment

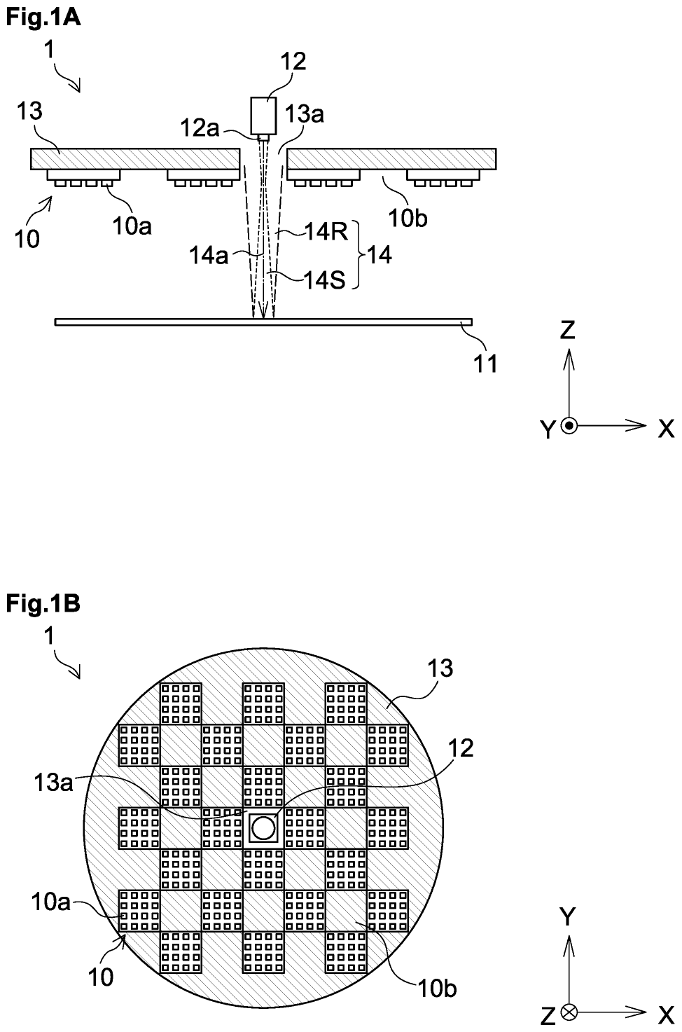

FIG. 1A is a schematic view illustrating a configuration of a first embodiment of the optical heating device 1. The optical heating device 1 in the first embodiment illustrated in FIG. 1A is formed of LED units 10 that emit heating light for heating a heating target 11, and a radiation thermometer 12 that measures the temperature of the heating target 11. The LED units 10 are held in a coplanar manner by a holder 13.

The XYZ coordinate system as shown in FIG. 1A will be referred to as required in the description below. One surface of the heating target 11 (surface irradiated with the heating light) is defined as the X-Y plane, and the direction perpendicular to this plane is defined as the Z direction. The LED units 10 are disposed to face the heating target 11 in the Z direction.

FIG. 1B is a schematic view of the optical heating device 1 of FIG. 1A when viewed from the heating target 11, i.e., in the Z direction. As illustrated in FIG. 1B, in the optical heating device 1 of the first embodiment, a plurality of the LED units 10 that are configured by square substrates are held by the holder 13 that has a circular shape. The plurality of LED units 10 are disposed with equally distanced spaces 10b, but the LED units may not necessarily be equally spaced apart.

A plurality of LED elements 10a are disposed on the same substrate of each LED unit 10, the emission surfaces emitting heating light of the LED elements 10a being disposed to face the heating target 11 in the Z direction. The LED units 10 are arranged with spaces 10b therebetween on the XY plane and held by the holder 13.

It should be noted that FIG. 1B, which is a schematic view, shows only a small number of LED elements 10a on the same LED unit 10. In actuality, several tens to several hundreds LED elements 10a are disposed on each LED unit 10. With a plurality of LED units 10 carrying several tens to several hundreds LED elements 10a disposed thereon, the optical heating device 1 as a whole has several hundreds to several thousands LED elements 10a.

The holder 13 has an aperture part 13a communicated to a specific one of the spaces 10b in a direction perpendicular to the surface of the substrates of the LED units 10. The aperture part 13a is formed with the same width as the spaces 10b formed between the LED units 10, but may have a different width from that of the space 10b.

As shown in FIG. 1B, the aperture part 13a is provided in a central portion of the holder 13 and communicated to one of the spaces 10b formed between the LED units 10. The radiation thermometer 12 is disposed at a position farther from the LED elements 10a than the holder 13 and such that the light receiving area 14 is contained in the aperture part 13a and the space 10b communicated to the aperture part 13a.

The radiation thermometer 12 is disposed such that a light receiver 12a for receiving the light is to face the heating target 11. For convenience of explanation, the drawing illustrates the light receiving area 14 that covers the area of measurement of infrared light by the radiation thermometer 12, and the light receiving direction 14a to which the light receiver 12a is oriented.

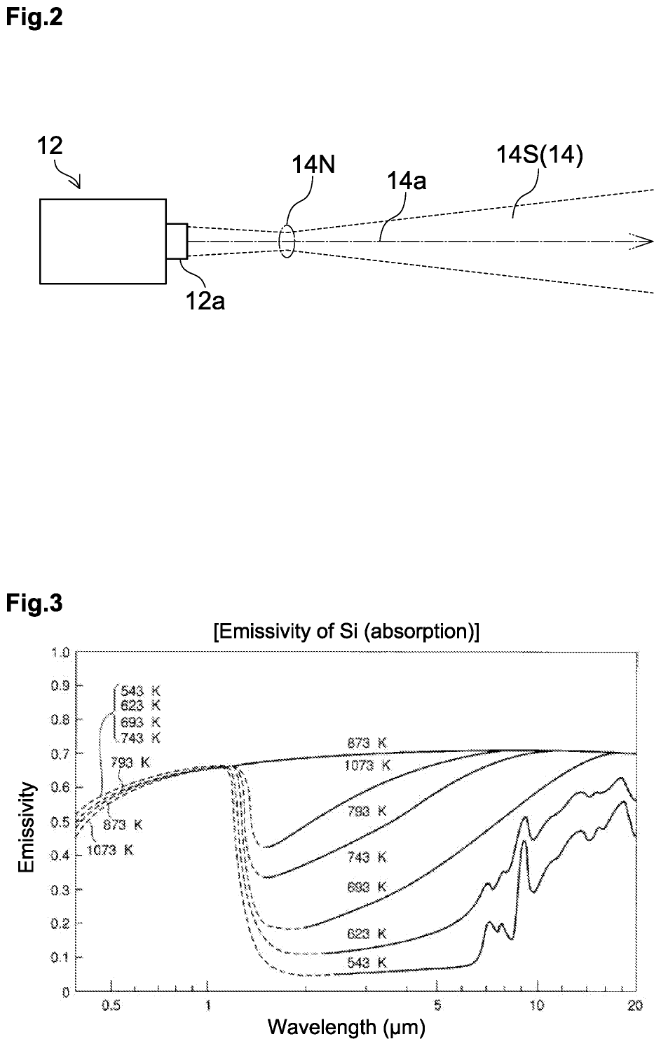

FIG. 2 is a schematic view illustrating the configuration of the radiation thermometer 12 and the light receiving area 14. The radiation thermometer 12 stores therein the information on the relationship between the intensity of received infrared light and the temperature of the heat source that emits the infrared light of this intensity. The radiation thermometer 12 measures the intensity of infrared light entering the light receiver 12a, and calculates temperature on the basis of the measured infrared intensity and the stored information.

Since the radiation thermometer 12 measures the temperature of the heating target 11 from the infrared light that enters the light receiver 12a, it is capable of measuring the temperature of the heating target 11 only within the area where infrared light enters the light receiver 12a. Namely, the area where the light receiver 12a can receive the infrared light is the light receiving area 14.

The range of the light receiving area 14 can be adjusted by an optical system such as a lens and a mirror. The commercially available radiation thermometer 12 contains a plurality of built-in optical systems so that the light receiving area 14 is set in accordance with the object to be measured or purpose of use. One example of such light receiving area 14 is illustrated in FIG. 2. Many radiation thermometers 12 are equipped with a lens for receiving infrared light. The area 14N where the light receiving area 14 has the smallest width corresponds to the focus point of this lens.

The light receiving area 14 in the first embodiment includes a light receiving area 14S where infrared light from the heating target 11 directly enters the light receiver 12a, and a light receiving area 14R where infrared light reflected by a surface facing the light receiver 12a of the heating target 11 enters the radiation thermometer 12. For example, it is the area defined by dashed lines in FIG. 1A.

In the first embodiment, the LED elements 10a are disposed such as not to be located inside the light receiving area 14. This configuration inhibits reception of infrared light radiated from the LED elements 10a as the heat source by the light receiver 12a of the radiation thermometer 12, so that the accuracy of the measurement by the radiation thermometer 12 of the intensity of the infrared light radiated from the heating target 11 can be improved.

Now, the heating light emitted by the LED elements 10a and the range of wavelengths to be measured by the radiation thermometer 12 are explained. The heating light emitted by the LED elements 10a may be any of the ultraviolet, visible light, and infrared light. As mentioned above, the LED elements 10a are configured to emit heating light of a wavelength outside the range of wavelengths to be measured by the radiation thermometer 12. One example would be that the LED elements 10a mainly emit a wavelength of 405 nm, while the range of wavelengths to be measured by the radiation thermometer 12 is from 0.8 μm to 1.0 μm.

In the case where the heating target 11 is a silicon wafer as described above, the range of wavelengths to be measured by the radiation thermometer 12 should preferably be from 1.9 μm to 4.0 μm. FIG. 3 is a graph illustrating a relationship between wavelengths of infrared light and emissivity at various temperatures of a silicon wafer. Silicon wafers are known to have an emissivity characteristic shown in FIG. 3, i.e., the emissivity of the silicon wafer is less susceptible to infrared light radiated from other heat sources in the range of 1.9 μm to 4.0 μm, particularly at a temperature of 350° C. (623 K) or less, so that the accuracy of temperature measurement will be higher.

### Second Embodiment

The configuration of a second embodiment of the optical heating device 1 of the present invention is described, centering on features different from the first embodiment.

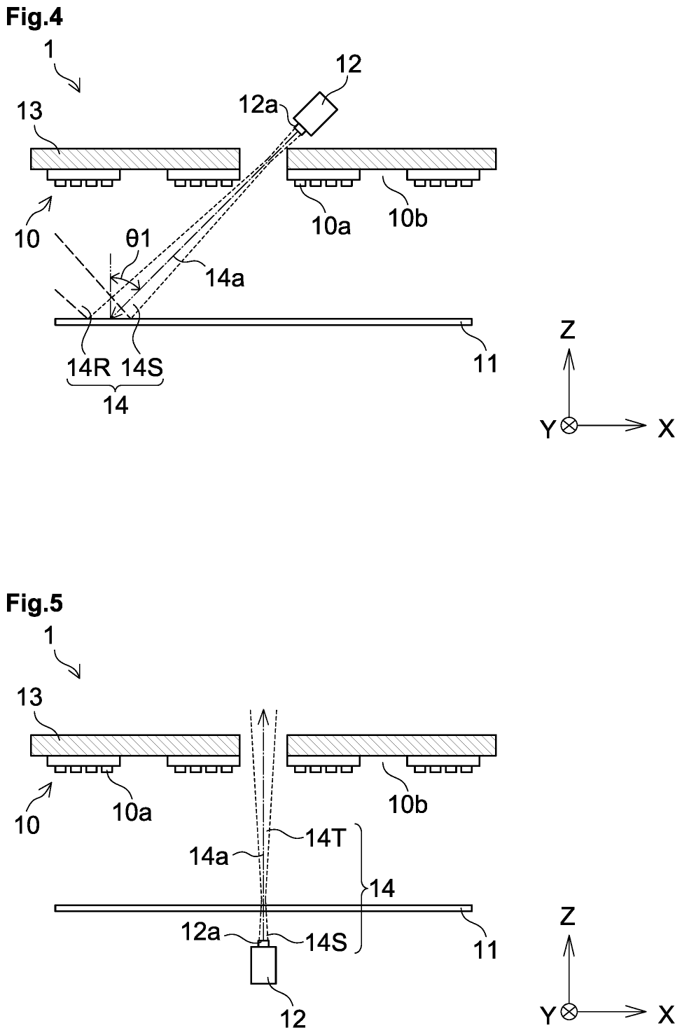

FIG. 4 is a schematic view illustrating the configuration of the second embodiment of the optical heating device 1. As illustrated in FIG. 4, in the second embodiment, the light receiving direction 14a in which the light receiver 12a of the radiation thermometer 12 is oriented is inclined by an angle θ1 relative to the Z direction. However, similarly to the first embodiment, the radiation thermometer 12 is disposed at a position farther from the LED elements 10a than the holder 13 and such that the light receiving area 14 is contained in the aperture part 13a and the space 10b communicated to the aperture part 13a.

The angle θ1 is set such that the light receiving area 14 does not contain any LED element 10a. From the viewpoint of temperature measurement of the heating target 11, it is preferably 60 degrees or less. More preferably, it should be as small as possible in the range not exceeding 30 degrees. Depending on the distance from the heating target 11, it may sometimes be preferable to provide the radiation thermometer 12 at one end of the heating target 11.

The light receiving area 14 in the second embodiment includes a light receiving area 14S where infrared light from the heating target 11 directly enters the light receiver 12a, and a light receiving area 14R where infrared light reflected by a surface facing the light receiver 12a of the heating target 11 enters the radiation thermometer 12.

In the second embodiment, too, the LED elements 10a are disposed such as not to be contained in the light receiving area 14 so that the infrared light radiated from the LED elements 10a hardly enters the light receiver 12a of the radiation thermometer 12. Thus, the accuracy of the measurement by the radiation thermometer 12 of the intensity of the infrared light radiated from the heating target 11 can be improved.

### Third Embodiment

The configuration of a third embodiment of the optical heating device 1 of the present invention is described, centering on features different from the first embodiment and second embodiment.

FIG. 5 is a schematic view illustrating the configuration of the third embodiment of the optical heating device 1. As illustrated in FIG. 5, in the third embodiment, the radiation thermometer 12 is disposed on the opposite side from the side where the LED units 10 are disposed relative to the heating target 11 (on the negative side of the Z direction in the drawing) such that the light receiver 12a faces the heating target 11. The radiation thermometer is disposed such that the LED elements 10a are not contained in the light receiving area 14.

The light receiving area 14 in the third embodiment includes a light receiving area 14S where infrared light from the heating target 11 directly enters the light receiver 12a, and a light receiving area 14T where infrared light passes through the heating target 11 and enters the radiation thermometer 12.

In the third embodiment, too, the LED elements 10a are disposed such as not to be contained in the light receiving area 14 so that the infrared light radiated from the LED elements 10a hardly enters the light receiver 12a of the radiation thermometer 12. Thus, the accuracy of the measurement by the radiation thermometer 12 of the intensity of the infrared light radiated from the heating target 11 can be improved.

### Fourth Embodiment

The configuration of a fourth embodiment of the optical heating device 1 of the present invention is described, centering on features different from the first embodiment, second embodiment, and third embodiment.

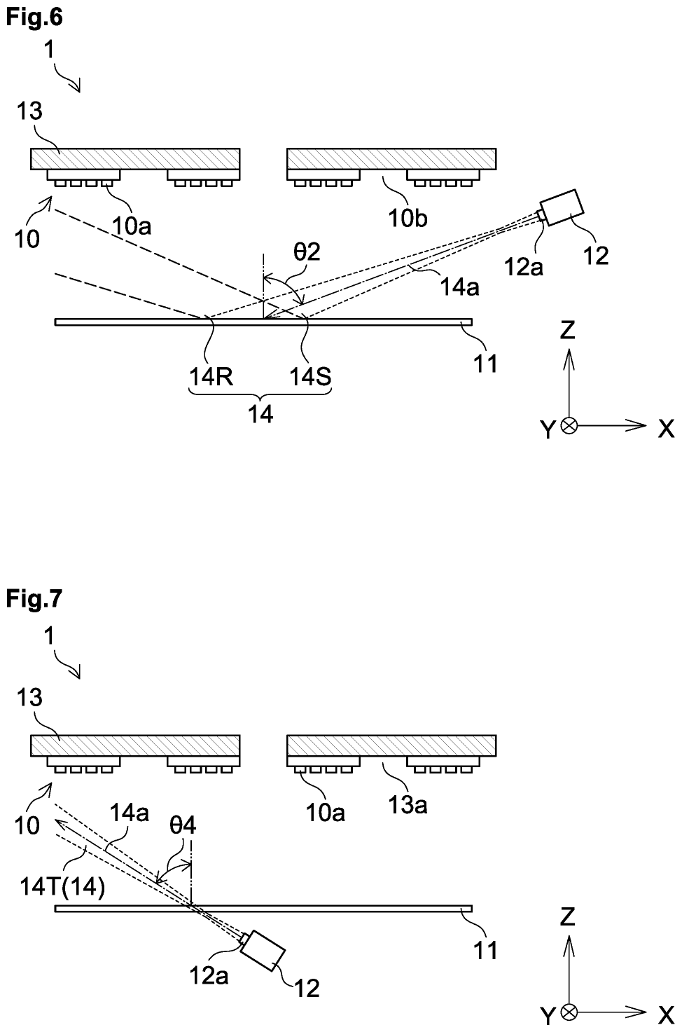

FIG. 6 is a schematic view illustrating the configuration of the fourth embodiment of the optical heating device 1. As illustrated in FIG. 6, in the fourth embodiment, the light receiving direction 14a in which the light receiver 12a of the radiation thermometer 12 is oriented is inclined by an angle θ2 relative to the Z direction. However, unlike the first embodiment, the radiation thermometer 12 is disposed on one side of the heating target 11 so that the light receiving area 14 is not contained in the aperture part 13a and the space 10b communicated to the aperture part 13a.

The angle θ2 is set such that the light receiving area 14 does not contain any LED element 10a. From the viewpoint of temperature measurement of the heating target 11, it is preferably 60 degrees or less. More preferably, it should be as small as possible in the range not exceeding 30 degrees. Depending on the distance from the heating target 11, it may sometimes be preferable to provide the radiation thermometer 12 at one end of the heating target 11.

The light receiving area 14 in the fourth embodiment includes a light receiving area 14S where infrared light from the heating target 11 directly enters the light receiver 12a, and a light receiving area 14R where infrared light reflected by a surface facing the light receiver 12a of the heating target 11 enters the radiation thermometer 12.

In the fourth embodiment, too, the LED elements 10a are disposed such as not to be contained in the light receiving area 14 so that the infrared light radiated from the LED elements 10a hardly enters the light receiver 12a of the radiation thermometer 12. Thus, the accuracy of the measurement by the radiation thermometer 12 of the intensity of the infrared light radiated from the heating target 11 can be improved.

### Other Embodiments

Other embodiments of the optical heating device 1 are described below.

<1> FIG. 7 is a schematic view illustrating the configuration of another embodiment of the optical heating device 1. As illustrated in FIG. 7, this embodiment is different from the third embodiment in that the light receiving direction 14a in which the light receiver 12a of the radiation thermometer 12 is oriented is inclined by an angle θ4 relative to the Z direction. Namely, as opposed to the third embodiment in which the light receiving area 14 is contained in the aperture part 13a and the space 10b communicated to the aperture part 13a, the light receiving area is not contained in the aperture part 13a and the space 10b communicated to the aperture part 13a in this embodiment.

<2> There may be disposed a plurality of radiation thermometers 12. For example, the optical heating device 1 may include a radiation thermometer 12 that measures the temperature of a central portion of the heating target 11, and a radiation thermometer 12 that measures the temperature of a peripheral portion.

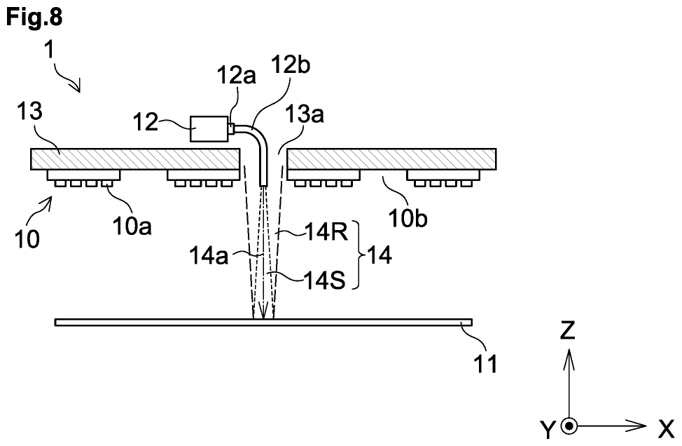

By measuring temperature at a plurality of points, the optical heating device 1 can determine a temperature difference between the central portion and the peripheral portion of the heating target 11, and can heat the entire heating target 11 uniformly by separately controlling the LED units 10 emitting heating light toward the central portion of the heating target 11 and the LED units 10 emitting heating light toward the peripheral portion.

<3> FIG. 8 is a schematic view illustrating the configuration of another embodiment of the optical heating device 1. As illustrated in FIG. 8, the radiation thermometer 12 may include an optical waveguide 12b (for example an optical fiber) for guiding the infrared light radiated from the heating target 11 toward the light receiver 12a of the radiation thermometer 12.

This configuration allows the radiation thermometer 12 to guide the infrared light radiated from the heating target 11 efficiently toward the light receiver 12a by adjusting the position of the optical waveguide 12b ,thus the radiation thermometer is less susceptible to the infrared light radiated from the LED elements 10a. Moreover, the configuration allows the radiation thermometer 12 to orient the light receiver 12a to any direction, so that the optical heating device 1 as a whole could be made smaller.

<4> Moreover, the optical heating device 1 according to the present invention may include a light emission window between itself and the heating target 11 in the emission direction of the heating light from the LED elements. In a production process, in particular, sometimes it is necessary to supply a predetermined reactive gas to the heating target 11. When applying the optical heating device 1 to a chamber where such processing is performed, it is essential to protect the optical heating device 1 with a light emission window. In this case, it is desirable that the measurement wavelength range of the radiation thermometer 12 is selected in a range in which the transmittance of the light emitting window is high. Specifically, the range of wavelengths, 50% or more of which is passed through the light emission window, is selected.

For the material of the light emission window, for example, quartz glass may be adopted. Quartz glass may sometimes exhibit a large absorption peak, particularly at 2.73 μm, depending on the rate of OH contained therein. Therefore, in cases where the configuration described above is employed, it is preferable that the radiation thermometer 12 have a range of wavelengths to be measured of 1.9 μm to 2.6 μm, or about 2.8 μm to 4.0 μm. The more preferable range of wavelengths to be measured by the radiation thermometer is 1.9 μm to 2.6 μm, from the viewpoint of minimizing the influence of heat dissipation from other components (ambient light).

<5> The configurations of the optical heating device 1 described above are merely examples. The present invention is not limited to the various illustrated configurations.

What is claimed is:

1. An optical heating device for heating a heating target, comprising:
an LED element disposed to face the heating target and emitting light for heating the heating target; and
a radiation thermometer having a light receiver and measuring a temperature of a heat source that is a source of infrared light that enters the light receiver in accordance with an intensity of the infrared light in a predetermined range of wavelengths to be measured,
the light receiver having a light receiving area where the light receiver is capable of receiving light, and being disposed such that the light receiving area contains the heating target,
the LED element emitting light of a wavelength outside the range of wavelengths to be measured by the radiation thermometer and being disposed outside the light receiving area.

2. The optical heating device according to claim 1, wherein the radiation thermometer is disposed on an opposite side from a side where the LED element is disposed relative to the heating target.

3. The optical heating device according to claim 1, wherein the radiation thermometer is disposed on a same side as a side where the LED element is disposed relative to the heating target.

4. The optical heating device according to claim 3, wherein
the optical heating device comprises a plurality of LED units, each LED unit including a plurality of the LED elements disposed on a same substrate,
the plurality of LED units being disposed with a space therebetween in a direction parallel to a surface of the substrate,
the radiation thermometer being disposed such that the light receiving area of the light receiver is contained in a specific one of the spaces.

5. The optical heating device according to claim 4, further comprising a holder for holding the plurality of LED units in a coplanar manner,
the holder including an aperture part communicated to the specific one of the spaces in a direction perpendicular to the surface of the substrate,
the light receiver of the radiation thermometer being disposed farther from the LED elements than the holder and such that the light receiving area of the light receiver is contained in the aperture part and the specific one of the spaces.

6. The optical heating device according to claim 4, wherein the radiation thermometer includes an optical waveguide for guiding infrared light radiated from the heating target toward the light receiver.

7. The optical heating device according to claim 1, wherein the range of wavelengths to be measured is from 1.9 μm to 4.0 μm.

8. The optical heating device according to claim 5, wherein the radiation thermometer includes an optical waveguide for guiding infrared light radiated from the heating target toward the light receiver.

9. The optical heating device according to claim 2, wherein the range of wavelengths to be measured is from 1.9 μm to 4.0 μm.

10. The optical heating device according to claim 3, wherein the range of wavelengths to be measured is from 1.9 μm to 4.0 μm.

11. The optical heating device according to claim 4, wherein the range of wavelengths to be measured is from 1.9 μm to 4.0 μm.

12. The optical heating device according to claim 5, wherein the range of wavelengths to be measured is from 1.9 μm to 4.0 μm.

13. The optical heating device according to claim 6, wherein the range of wavelengths to be measured is from 1.9 μm to 4.0 μm.

14. The optical heating device according to claim 8, wherein the range of wavelengths to be measured is from 1.9 μm to 4.0 μm.
